(19) United States
(12) Patent Application Publication
(10) Pub. No.: US 2011/0179342 A1
(43) Pub. Date: Jul. 21, 2011

(54) COMMUNICATION ERROR MONITORING SYSTEM OF POWER DEVICE BASED ON ETHERNET AND METHOD THEREOF

(75) Inventor: Kyung ho KIM, Cheongju (KR)

(73) Assignee: LS INDUSTRIAL SYSTEMS CO., LTD.

(21) Appl. No.: 12/980,142

(22) Filed: Dec. 28, 2010

(30) Foreign Application Priority Data
Jan. 18, 2010 (KR) 10-2010-0004347

(51) Int. Cl. H03M 13/09; G06F 11/10

(52) U.S. Cl. 714/807; 714/E11.032

(57) ABSTRACT

Disclosed is communication error monitoring system and method thereof. In the present disclosure, a master lower-level device, at least one or more slave lower-level devices, and an upper-level monitoring unit are inter-connected via Ethernet, wherein the upper-level monitoring unit receives information of lower-level devices determined as with communication error from the master lower-level device to request and collect necessary data with the slave lower-level devices except for the lower-level devices with the communication error through Ethernet. And thus, a communication delay unnecessary of an entire power system is eliminated and a real time response and stability of a system is enhanced.

### CROSS-REFERENCE TO RELATED APPLICATIONS

Pursuant to 35 U.S.C. §119(a), this application claims the benefit of earlier filing date and right of priority to Korean Application No. 10-2010-0004347, filed on Jan. 18, 2010, the contents of which are hereby incorporated by reference herein in their entirety.

### BACKGROUND OF THE DISCLOSURE

1. Field of the Disclosure

The present disclosure relates to an Ethernet-based power monitoring system, in particular to, communication error monitoring system and method thereof of a power device based on Ethernet capable of swiftly and accurately diagnosing communication error in a case of communication using Ethernet between a plurality of lower-level apparatuses and an upper-level monitoring unit.

2. Description of the Related Art

Under a conversion circumstance of a communication in power systems such as a protection relay and a PLC (Programmable Logic Controller) installed in a substation gradually changing from a serial line to Ethernet, when communication error occurs, because a switch and an optic converter, a cable, other apparatuses are compositely related, it is difficult to find a cause on error.

A protection relay is an apparatus for protecting a network from various accidents of a line such as an overcurrent, a short circuit, and a ground fault, and since it periodically reports a line state of the actual spot and measurement data to an upper-level monitoring unit, reliability in communication with the upper-level monitoring unit is required. Lower-level apparatuses, such as protection relay or switch transceive important data for network and measurement via Ethernet. However, in view of the fact that there are no I/O devices for performing debugging responsive to communication error, an examination technology for high-priced equipment and network failure determination is additionally needed. And, in a case of occurrence of communication error, it takes many hours to analyze a cause of error and to restore a normal-state throughout the system. This means that a monitoring and control system has a fatal drawback on account of a communication.

FIG. 1 indicates a diagram of an Ethernet-based power system according to the prior art, which includes an upper-level monitoring unit 10, a hub 30 and a plurality of protection relays 50a-50n.

Each kind of protection relays 50a-50n installed in a transformer communicates with the upper-level monitoring unit 10 such as an HMI apparatus through Ethernet and the hub 30.

When the upper-level monitoring unit 10 requests a specific data to a first protection relay 50a via Ethernet, the first protection relay 50a transmits a requested data to the upper-level monitoring unit 10. At this time, other protection relays 50b-50n operate by internal arithmetic, protection algorithm, and the like.

Further, after communicating with the first protection relay 50a, the upper-level monitoring unit 10 requests a specific data to a second protection relay 50b in waiting, the second protection relay 50b transmits a requested data to the upper-level monitoring unit 10.

As such, the upper-level monitoring unit 10 proceeds a communication by continuously repeating the process in an order of 1st protection relay->2nd protection relay-> . . . ->nth protection relay->1st protection relay-> . . . .

That is, the upper-level monitoring unit 10 requests a predefined data by a user (binary data, analog data, event data, etc.) to protection relays, each of the protection relays acts to transmit the requested data.

At this time, when an error occurs on communication lines or devices due to various reasons, it is next to impossible to receive data requested by a specific protection relay, as shown in FIG. 2.

For example, in a case the second protection relay 50b has communication error; the upper-level monitoring unit 10 fails to receive data requested by the second protection relay 50b. And, when an error occurs, subsequent to failure correction, the upper-level monitoring unit 10 continues to request data to the next protection relay. After requesting data up to nth protection relay 50n with the last order and receiving all corresponding data, the upper-level monitoring unit 10 repeatedly acts to request data to the erred second protection relay 50b.

Herein, the upper-level monitoring unit 10 may instantly request again for a protection relay that has failed to make a response to the data request, or request again for data in the next turn.

As described above, the upper-level monitoring unit retransmits to the corresponding protection relay at a communication fault with a specific protection relay and inferringly determines normal/abnormal statuses of protection relays at a repeated communication fault.

Such an error diagnosis according to a communication state of protection relays requires a considerable time in determining an error state, and an error check process makes it difficult to monitor and control a system in real time.

Generally, the upper-level monitoring unit incessantly transmits a data request, at communication error with protection relays or at a communication failure due to a break of a communication line, and a fault of protection relays. Herein, because communication error with a protection relay continues even in case a collision between data does not cause an error, a continuous data request of protection relays may impede an effective operation of a system.

Also, a more intelligent upper-level monitoring unit may be configured not to perform a data request to a protection relay with which a communication fails, but it is difficult to reflect a state of protection relays in real time and constructing a system of which is not easy. Particularly, in a case components of protection relays are tangled and in many numbers, it is difficult to reflect the status of protection relays in real time.

In a data communication over Ethernet, data transmission/reception between a upper-level monitoring unit and a protection relay needs a time span of about 4 msec through 50 msec in a normal case, but in an abnormal case there needs a time in between 1 sec and 5 sec and a delay time waiting for data at the upper-level monitoring unit. Thus, as protection relays much more increases, a delay time occurring through the system increase in arithmetical progression.

Therefore, with a reference data capable of determining a communication normal/abnormal state of multiple devices through the system, the upper-level system can do an intelligent transmission/reception enabling of, based on the result, requiring data for a normal state device and on the contrary not requiring data for an abnormal state device, thus changing an operation method of a currently ineffective system.

### SUMMARY OF THE DISCLOSURE

The present disclosure is related to communication error monitoring system of an Ethernet-based power device and a method thereof.

The present disclosure may be characterized in that the system comprises at least one or more slave lower-level devices for transmitting a response frame for a status check frame received from a master lower-level device, the master lower-level device for transmitting a status check frame to the slave lower-level devices, for determining communication error according to the response frame received from the slave lower-level devices, and for transmitting information on the lower-level device determined as with communication error to a upper-level monitoring unit, and the upper-level monitoring unit for receiving the information of the lower-level devices with the communication error from the master lower-level device, for requesting and collecting necessary data with the slave lower-level devices except for the lower-level devices with the communication error through Ethernet, wherein the master lower-level device, the slave lower-level devices, and the upper-level monitoring unit are connected via Ethernet between one another. And thus, the present disclosure provides communication error monitoring system and method thereof of an Ethernet based power device capable of diagnosing communication error swiftly and precisely in a case of communicating using Ethernet between a plurality of lower-level devices and an upper-level monitoring unit.

The present disclosure detects a specific lower-level device in real time with communication error occurred through a mutual communication between lower-level devices in a power system and reports information on an error occurred lower-level devices to the upper-level monitoring unit. And thus, it is an object of the disclosure to provide communication error monitoring system and method thereof of an Ethernet based power device possibly eliminating an unnecessary communication delay of an entire power system and improving a real-time response of a system.

To achieve the above-mentioned objective, communication error system of the present disclosure, characterized in that the system comprises at least one or more slave lower-level devices for transmitting a response frame for a status check frame received from a master lower-level device, the master lower-level device for transmitting a status check frame to the slave lower-level devices, for determining communication error according to the response frame received from the slave lower-level devices, and for transmitting information on the lower-level device determined as with communication error to a upper-level monitoring unit, and the upper-level monitoring unit for receiving the information of the lower-level devices with the communication error from the master lower-level device, for requesting and collecting necessary data with the slave lower-level devices except for the lower-level devices with the communication error through Ethernet, wherein the master lower-level device, the slave lower-level devices, and the upper-level monitoring unit are connected via Ethernet between one another.

Specifically, the master lower-level device is characterized by repeatedly transmitting a status check frame to a slave lower-level device from which the response frame is not received, and determining the slave lower-level device as with the communication error in a case an unsuccessfully received times of a response frame exceeds a predefined reference times with regard to the repeatedly transmitted status check frame.

And, the master lower-level device is characterized by repeatedly transmitting a status check frame to the lower-level device determined as with the communication error, and informing the upper-level monitoring unit that communication error is repaired in a case a response frame is received from the lower-level device.

To achieve the aforementioned object, a monitoring method of communication error of the disclosure comprises, generating and transmitting a status check frame to a slave lower-level device interconnected via Ethernet according to a preset period by a master lower-level device, determining whether a response frame from the slave lower-level device is received, increasing a response failure times of the slave lower-level device, when the response frame from the slave lower-level device is not received, repeating a status check frame transmission to the slave lower-level device, determining if an accumulated response failure times exceeds a preset reference times and determining the slave lower-level device as with communication error in the case of exceeding the reference times, and transmitting in real time information on the lower-level device determined as with the communication error to an upper-level monitoring unit.

And, after determining the response frame is received, the method is characterized by further comprising transmitting a status check frame to other slave lower-level devices connected through Ethernet in a case of receiving the response frame from the slave lower-level device, and determining whether a response frame from them is received.

Also, the method is characterized in that after determining if the accumulated response failure times exceeds the preset reference times, as a determination result, in an unexceeding case, the master lower-level device retransmits a status check frame to the slave lower-level device after a certain time and determines whether a response frame is received.

A monitoring method of communication error of the present disclosure is characterized by further comprising not requesting data transmission to the lower-level device with the communication error by the upper-level monitoring unit.

### BRIEF DESCRIPTION OF THE DRAWINGS

FIGS. 1 and 2 are diagrams indicating an Ethernet-based power system according to the prior art;

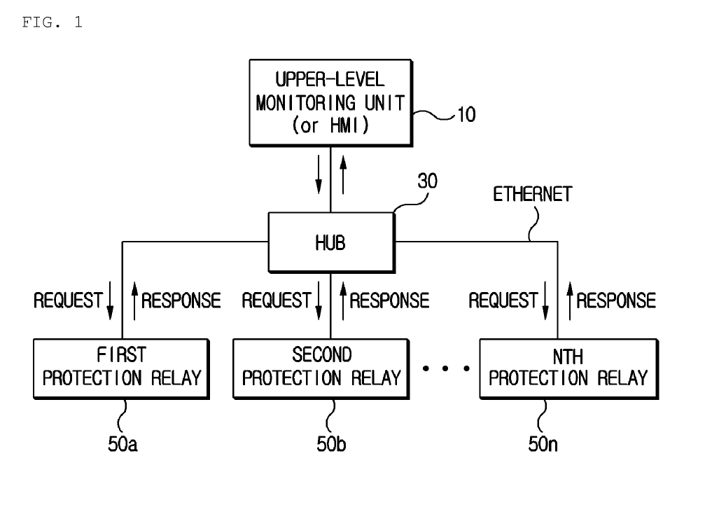

FIG. 3 is a diagram indicating an Ethernet-based power system according to the present disclosure;

FIG. 4 is a diagram indicating a detailed construction of a protection relay applied to the present disclosure;

FIG. 5 is a diagram shown to describe communication error check method of a power system according to FIG. 3; and

FIG. 6 is a flow chart indicating communication error check procedure according to an exemplary embodiment of the present disclosure.

### REFERENCE NUMERALS OF MAIN PART OF DRAWINGS

10: UPPER-LEVEL MONITORING UNIT
100a-100n: LOWER-LEVEL DEVICE (PROTECTION RELAY)
100a: 1^{St} LOWER-LEVEL DEVICE
100b-100n: 2^{nd} LOWER-LEVEL DEVICE

### DETAILED DESCRIPTION OF THE DISCLOSURE

Hereinafter, a preferred embodiment of the present disclosure will be explained in detail by reference to the accompanying drawings. Same components of the drawings are marked as a same possible sign where they are. Also, a detailed description of known-functions and constructions will be omitted as they can unnecessarily obscure substances of the disclosure.

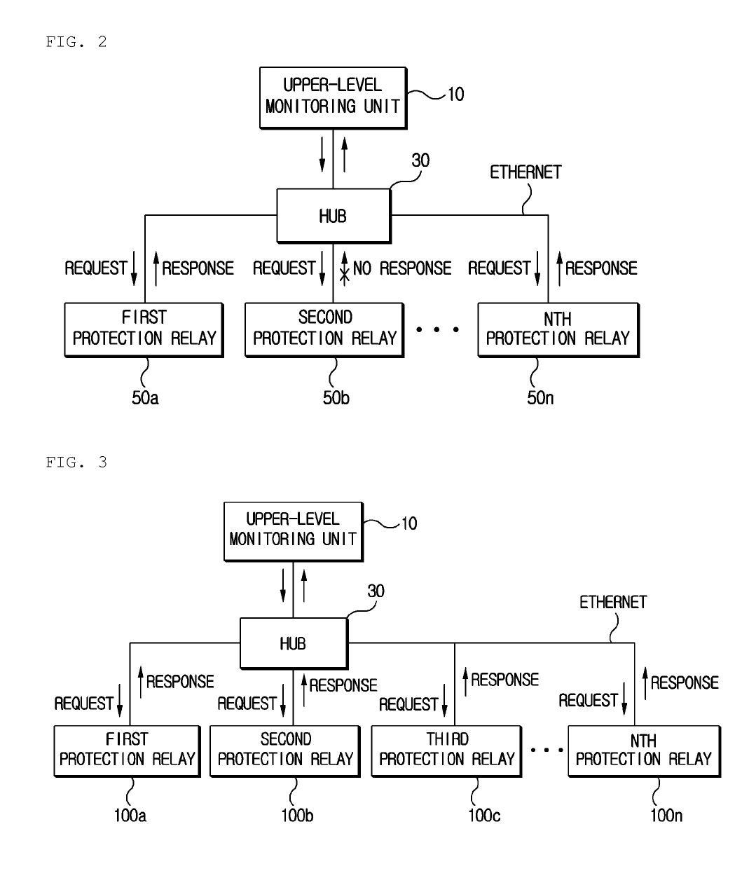

FIG. 3 is a diagram indicating an Ethernet-based power system pursuant to the present disclosure, in which the constituent comprises an upper level monitoring unit 10, a hub 30 and a plurality of protection relays 100a-100n.

Note that a lower-level device of an embodiment of the present disclosure is described in a case of a protection relays, for example, for briefness of description but not limited to this. The lower-level device may be selected from any one of a protection relay, a PLC (Programmable Logic Controller), a measurement instrument, and a power monitoring device, and the protection relay is called an IED (Intelligent Electronic Device).

The upper-level monitoring unit 10 is connected to a plurality of protection relays 100a-100n via the hub 30 and Ethernet, which may consist of a host computer such as an HMI (Human Machine Interaction) repeatedly requesting necessary data to each protection relay 100a-100n at a certain period and manageably storing a response message received from the protection relay.

The protection relays 100a-100n, to which specific data is requested from the upper-level monitoring unit 10, extracts the requested data and transmits the upper-level monitoring unit 10 via Ethernet.

Herein, the protection relays 100a-100n are divided into a master and at least one slave, the master checks a communication state of each slave by communicating with each of slave. In an embodiment, for convenience's sake, it is assumed that a first protection relay 100a is a master, and remaining protection relays 100b-100n are slaves.

The slave protection relays 100b-100n transmits a response frame in response to a status check frame requested from the master protection relay 100a. And, the master protection relay 100a transmits a status check frame to a certain slave protection relay connected via Ethernet. The master protection relay 100a determines communication error occurrence according to a response frame received or not from each slave protection relay and transmits information on the protection relay with communication error to the upper-level monitoring unit 10.

The upper-level monitoring unit 10 generally acts to request and collect necessary data of a plurality of protection relays connected through Ethernet. And, on receiving the information on the protection relay with communication error from the master protection relay 100a, the upper-level monitoring unit 10 excludes the corresponding protection relay and requests data only for a remaining protection relay.

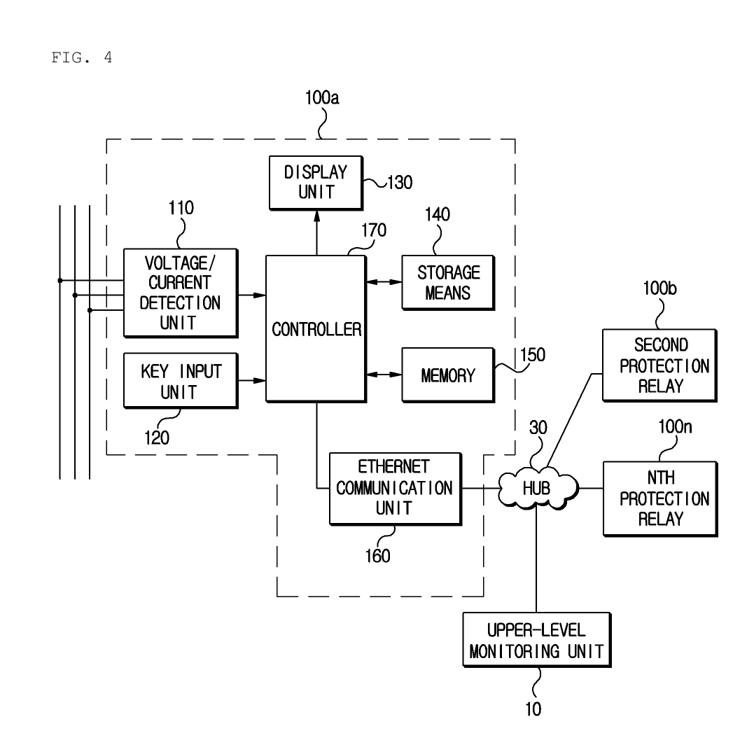

A detailed construction of the specific protection relay 100a is indicated herein in FIG. 4.

As shown in the figure, the protection relay 100a comprises a voltage/current detection unit 110, a key input unit 120, a display unit 130, a storage means 140, a memory 150, Ethernet communication unit 160, and a control unit 170.

The voltage/current detection unit 110 comprises a potential transformer (PT) converting a high-voltage on a line to a low-voltage by a certain ratio, and a current transformer (CT) converting a high-current flowing on a line to a low-current by a certain ratio.

The key input unit 120 receives a user setting command such as each kind of measurement and operation modes or a backup period of the protection relay 100a.

The display unit 130 consists of an LCD displaying various power source state detected by the voltage/current detection unit 110 and each of setting command through the key input unit 120 as characters or graphics.

The storage means 140 consists of a hard disk (HDD) or a nonvolatile memory storing by item, under the control of the control unit 170, event data, accident data, wave data, demand data and key-manipulation data inputted through the voltage/current detection unit 110 and the key-input unit 120.

The memory 150 stores information on a communication state and error with other protection relays 100b-100n connected via Ethernet.

Ethernet communication unit 160 is responsible for data transmission/reception connected with the upper-level monitoring unit 10 and other protection relays 100b˜100n via Ethernet.

The control unit 170 controls an operation of said each component, wherein it stores the measurement data from the voltage/current detection unit 110 in the storage means 140, analyzes a request frame transmitted by the upper-level monitoring unit 10, makes a frame, and transmits it to the upper-level monitoring unit 10 through Ethernet communication unit 160. Herein, the measurement data includes event data, accident data, wave data, demand data, key-manipulation data and so on.

In addition, the control unit 170 transmits a status check frame to other protection relays 100b˜100n connected through Ethernet on a preset period and requests a response thereof, and stores and manages communication error state based on a response from each protection relay 100b˜100n in the memory 150.

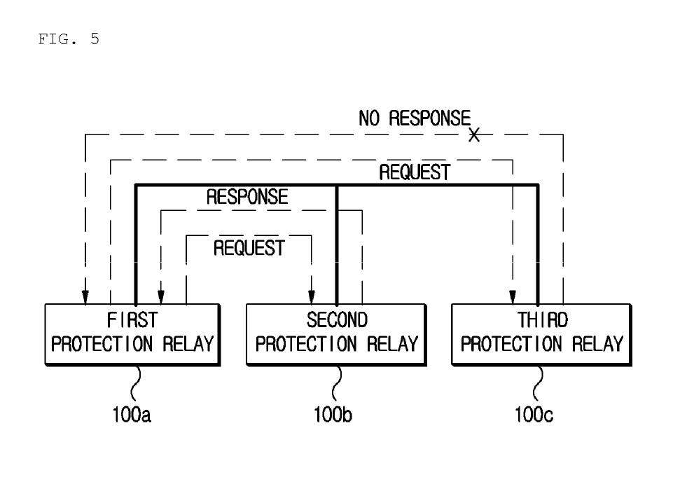

FIG. 5 is a diagram shown for the explanation of communication error check method of a power system according to FIG. 3. As illustrated in FIG. 5, in accordance with the present disclosure, any one protection relay 100a of a plurality of protection relays 100a-100c interconnected through Ethernet is set as a master, and the remaining protection relays 100b, 100c are set as slaves. Herein, the protection relays 100a-100c has a leveled inter-relationship, but for convenience's sake divided as a master and slaves.

The master protection relay 100a periodically transmits a status check frame to the slave protection relays 100b and 100c, which generate a response frame and respond to transmit it to the master protection relay 100a. Of course, a response frame would not be transmitted from the slave protection relay 100c having communication error.

The master protection relay 100a periodically transmits a status check frame to the slave protection relays 100b, 100c and checks communication error according to a response, and in case of communication error, transmits in real time information on the protection relay with the communication error to the upper-level monitoring unit 10.

Utilizing the information transmitted by the master protection relay 100a, the upper-level monitoring unit 10 does not request a data transfer from the protection relay 100c in the abnormal state.

That is, the master protection relay 100a transmitting a status information on an entire lower-level devices to the upper level monitoring unit 10 sends out a status check frame to other slave protection relays 100b˜100n in several msec intervals, and protection relays 100b˜100n having received the status check frame send out a response frame to the master protection relay 100a. At this time, reasoning that a communication with the upper-level monitoring unit 10 is the type of TCP/IP, it is possible to communicate between protection relays 100a˜100n with no effect on traffic.

Since each of protection relays 100a˜100n may have separately a TCP/IP socket for communication with the upper-level monitoring unit 10 and a socket for communication between protection relays 100a˜100n in real time using one Ethernet, it is possible for a master protection relay 100a to respond while processing commands from the upper-level monitoring unit 10.

In a continuous failure of communication with a specific protection relay, the master protection relay 100a sends out information on the protection relays with communication error to the upper-level monitoring unit 10, which does not request data for the protection relays with communication error. Therefore, since there is no delay time waiting for a respond from protection relays with communication error, a real time performance of an entire monitoring system may be improved.

At this time, the master protection relay 100a periodically checks a restoration to a normal state in real time even in protection relays with communication error and informs the upper-level monitoring unit 10 that it is normally recovered at the moment of being normally recovered.

Such a communication has no relationship with the upper-level monitoring unit 10 due to a broadcast mode, having no consequence on traffic of an entire system.

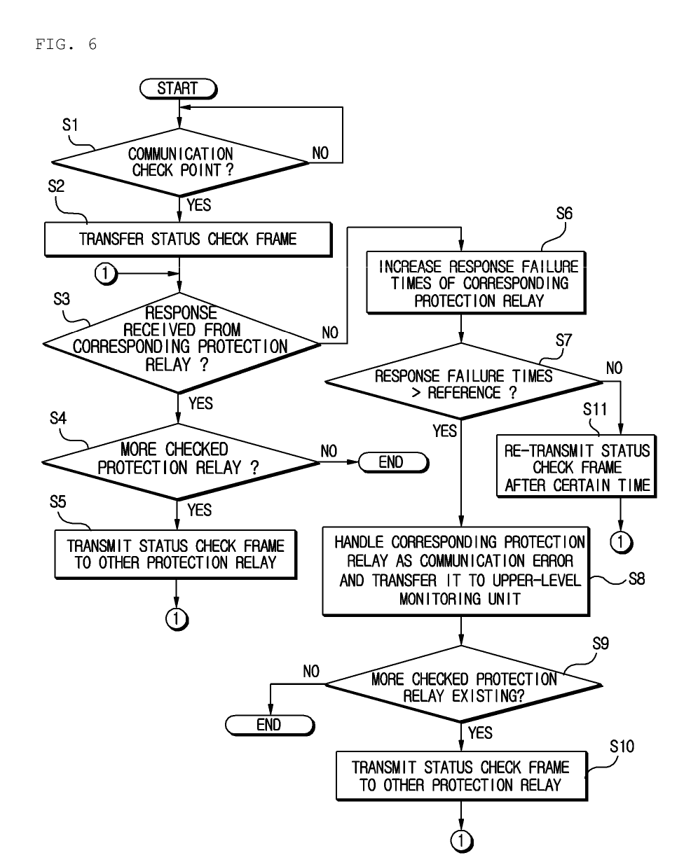

FIG. 6 is a flow chart indicating a real-time communication error monitoring method of an Ethernet-based power system according to the disclosure.

First, when a communication check point arrives at a predefined period (S1), a protection relay 100a set as a master generates and transmits a status check frame to a specific protection relay 100b designated as a slave (S2). Herein, the master protection relay 100a and at least one or more slave protection relays 100b˜100n are interconnected via Ethernet.

Successively, the master protection relay 100a determines whether a response frame is received from the slave protection relay 100b having received the status check frame (S3).

Herein, when the response frame from the slave protection relay 100b is received, the master protection relay 100a determines if there is any more protection relay to check a communication status (S4). If completed for the communication check with all slave protection relays 100b˜100n, the master protection relay 100a stands-by until a next communication check period.

However, in a case slave protection relays 100c˜100n to be checked remain, the master protection relay 100a transmits a status check frame to a next protection relay 100c (S5), and determines whether a response frame from said protection relay 100c is received (S3).

When a response frame from the slave protection relay 100c is not received, the master protection relay 100a increases a response failure times of the slave protection relay 100c (S6).

Continuingly, when the master protection relay 100a determines if an accumulated times of a respond failed protection relay 100c exceeds a reference times set to the memory 150 (S7), and in a case of exceeding the reference times, it decides a corresponding protection device 100c as a protection relay 100c having communication error and in real time transmits information on the protection relay 100c to the upper-level monitoring unit (S8).

The upper-level monitoring unit 10 may be arranged not to require data for a protection relay 100c in an abnormal state with communication error.

Succeedingly, the master protection relay 100a determines if there remains still more protection relays 100n to be checked for a communication status and then transmits a status check frame to a next protection relay 100n, and determines if a response frame from a protection relay 100n having received the status check frame is delivered (S3).

And, in a case the accumulated response failure times does not exceed the reference times, the master protection relay 100a retransmits a status check frame to a corresponding protection relay 100c having a response failure to check the response after a certain time (S11).

As such, the present disclosure can recognize communication error swiftly and precisely in the event of communication error through a communication between protection relays 100a˜100n.

In a power system, communication equipment with lower-level devices may stay at a communication failure continuously or instantly for several reasons. No way of knowing such a communication state, the upper-level monitoring unit 10 is constructed to perform a communication between lower-level devices like a pre-defined flow diagram as shown in FIG. 6.

That is, the present disclosure is constructed to monitor a normal/abnormal state on a communication of an entire system in real time and transfer the result to the upper-level monitoring unit 10 by performing a communication between lower-level devices. And, the upper-level monitoring unit 10 can pause the data communication with a protection relay having a currently poor communication state, thereby eliminating an unnecessary action attempting a communication with the communication-incapable protection relay.

A master protection relay of the present disclosure can variously transmit a status check frame in a various method, for example, the apparatus may transfer sequentially every several millisecond or transmit batchedly to the entire lower-level devices at certain time intervals, or precede a frame request and response by 1:1 in a polling mode. Based on an actual spot, a more proper method can be possibly used.

While the present disclosure has been described in detail hereinabove centered on preferred embodiments, it may be possible by those skilled in the art that other forms of embodiments different from the detailed description of the present disclosure can be realized within an essential technical scope of the disclosure.

What is claimed is:

1. Communication error monitoring system of an Ethernet based power device, the system comprising:
at least one or more slave lower-level devices for transmitting a response frame for a status check frame received from a master lower-level device;
the master lower-level device for transmitting a status check frame to the slave lower-level devices, for determining communication error according to the response frame received from the slave lower-level devices, and for transmitting information on the lower-level device determined as with communication error to a upper-level monitoring unit; and
the upper-level monitoring unit for receiving the information of the lower-level devices with the communication error from the master lower-level device, for requesting and collecting necessary data with the slave lower-level devices except for the lower-level devices with the communication error through Ethernet, wherein the master lower-level device, the slave lower-level devices, and the upper-level monitoring unit are connected via Ethernet between one another.

2. The system of claim 1, wherein the master lower-level device repeatedly transmits a status check frame to a slave lower-level device from which the response frame is not received, and determines the slave lower-level device as with the communication error in a case an unsuccessfully received times of a response frame exceeds a predefined reference times with regard to the repeatedly transmitted status check frame.

3. The system of claim 1, wherein the master lower-level device repeatedly transmits a status check frame to the lower-level device determined as with the communication error, and informs the upper-level monitoring unit that communication error is repaired in a case a response frame is received from the lower-level device.

4. The system of claim 1, wherein each of the master lower-level device and the slave lower-level devices is any one of a protection relay, a PLC (Programmable Logic Controller), a measurement instrument and a power monitoring device.

5. Communication error monitoring method of an Ethernet based power system, comprising:
generating and transmitting a status check frame to a slave lower-level device interconnected via Ethernet according to a preset period by a master lower-level device;
determining whether a response frame from the slave lower-level device is received;
increasing a response failure times of the slave lower-level device, when the response frame from the slave lower-level device is not received;
repeating a status check frame transmission to the slave lower-level device, determining if an accumulated response failure times exceeds a preset reference times and determining the slave lower-level device as with communication error in the case of exceeding the reference times; and
transmitting in real time information on the lower-level device determined as with the communication error to an upper-level monitoring unit.

6. The method of claim 5, wherein after determining the response frame is received, the method further comprises transmitting a status check frame to other slave lower-level devices connected through Ethernet in a case of receiving the response frame from the slave lower-level device, and determining whether a response frame from them is received.

7. The method of claim 5, wherein after determining if the accumulated response failure times exceeds the preset reference times, as a determination result, in an unexceeding case, the master lower-level device retransmits a status check frame to the slave lower-level device after a certain time and determines whether a response frame is received.

8. The method of claim 5, further comprises not requesting data transmission to the lower-level device with the communication error by the upper-level monitoring unit.
